(19) United States
(12) Patent Application Publication
(10) Pub. No.: US 2010/0216023 A1
(43) Pub. Date: Aug. 26, 2010

(54) Process for producing carbon nanostructure on a flexible substrate, and energy storage devices comprising flexible carbon nanostructure electrodes

(76) Inventors: Di Wei, Cambridge (GB); Alan Colli, Cambridge (GB); Markku Antti Kyosti Rouvala, Helsinki (FI); Husnu Emrah Unalan, Beysukent/ Ankara (TR); Pritesh Hiralal, Cambridgeshire (GB); Gahan Amaratunga, Cambridge (GB); Nalin Rupesinghe, Cambridge (GB)

Correspondence Address: WARE FRESSOLA VAN DER SLUYS & ADOLPHSON, LLP, BRADFORD GREEN, BUILDING 5, 755 MAIN STREET, P O BOX 224, MONROE, CT, 06468, US

(21) Appl. No.: 12/586,995

(22) Filed: Sep. 29, 2009

Related U.S. Application Data
(63) Continuation-in-part of application No. 12/319,933, filed on Jan. 13, 2009.

(51) Int. Cl. H01M 4/583; H01M 4/48; H01M 6/16; H01L 31/00; H01L 31/042; H01M 4/52; H01M 6/04; C23C 16/44; H01G 9/155

(52) U.S. Cl. 429/220; 429/231.8; 429/311; 136/256; 136/244; 429/221; 429/199; 427/255.28; 361/502; 977/742; 977/843

(57) ABSTRACT

An energy storage device structure comprises a first electrode layer, an electrolyte layer and a second electrode layer. At least one of the electrode layers comprise a metallic foil base layer and a layer of carbon nanotubes grown on the base layer, the carbon nanotube layer being arranged to face the electrolyte layer. The structure may be made in such a way that its width and length are much larger than its thickness, so that it can rolled up or folded and then hermetically sealed to form an energy storage unit. The layer of carbon nanotubes is grown on the metallic foil base layer by a chemical vapor deposition process at a temperature no higher than 550° C. The carbon nanotubes in the carbon nanotube layer are at least partially aligned in a direction that is perpendicular to the surface of the metallic base layer.

### CROSS REFERENCE TO RELATED APPLICATIONS

This application is a continuation-in-part application of U.S. patent application Ser. No. 12/319,933, filed on Jan. 13, 2009.

### DISCLOSURE OF JOINT RESEARCH AGREEMENT

The claimed invention was made under a joint research agreement between Nokia Corporation, Finland, and University of Cambridge, United Kingdom. The joint research agreement was in effect before the date the claimed invention was made, and the claimed invention was made as a result of activities undertaken within the scope of the joint research agreement.

### TECHNICAL FIELD

This disclosure relates to a process for producing carbon nanostructures, especially carbon nanotubes, on a flexible metallic substrate. Also the disclosure relates to energy conversion and storage devices, such as batteries and supercapacitors, having charge collectors made with the carbon nanotubes grown on the flexible substrate.

### BACKGROUND ART

The ever-increasing demand for portable electronic devices motivates technological improvements in energy conversion and storage units used in these devices. In developing the energy conversion and storage units, lightweight construction, long lifetime, high power density and flexibility to meet various design and power needs are important factors to consider. Examples of the energy conversion and storage units suitable for portable electronic devices include lithium ion batteries, lithium metal batteries and supercapacitors.

Lithium ion batteries are currently one of the most popular types of solid-state batteries for portable electronic devices, with one of the best energy-to-weight ratios, no memory effect, and a slow loss of charge when not in use. The three primary functional components of a lithium ion battery are anode, cathode and electrolyte, for which a variety of materials may be used. Commercially, the most popular material for the anode is graphite. The cathode may be made with an intercalation lithium compound such as lithium cobalt oxide, lithium iron phosphate, lithium manganese oxide, etc. An electrolyte is any substance containing free ions that behaves as an electrically conductive medium. Because they generally consist of ions in solution, electrolytes are also known as ionic solutions, but molten electrolytes and solid electrolytes are also possible.

Lithium metal batteries, or lithium metal polymer batteries, are rechargeable batteries that evolved from lithium-ion batteries. A lithium metal battery structure comprises a lithium metal anode, a polymer composite electrolyte and a cathode. Lithium metal batteries can be produced by stacking thin layers of these materials together. The resulting device structure is flexible, tough, and durable. The advantages of lithium metal polymer structure over the traditional lithium ion battery structure include lower cost of manufacturing and being more robust against physical damage.

Supercapacitors resemble a regular capacitor except that they offer very high capacitances in a small package. There are two types of supercapacitors, electrochemical double layer capacitor (EDLC) and peuseodocapacitor. Whereas a regular capacitor consists of conductive foil electrodes and a dry separator, the supercapacitor crosses into the battery technology territory by using electrodes and electrolyte that are similar to that of lithium ion/lithium metal batteries.

For enhanced charge storage capacity, electrode materials should have a high surface area. Recently, nanostructured materials are being used in rechargeable batteries. Nanostructured carbon, such as carbon nanotubes, carbon nanowires, carbon nanohorns and carbon nano-onions are being contemplated for replacing graphite. In the description that follows, carbon nanotube (CNT) is selected as a specific example of the nanostructured carbon materials. However, it is to be understood that the scope of the disclosure is not limited by any specific substance in any particular examples or embodiments.

CNT is a highly crystallized tubular structure of carbon. One single carbon nanotube is about a few nanometers in diameter and up to a hundred microns long. Millions of carbon nanotubes together may form a cluster of macroscopic material that is practically useful. CNTs have several important properties, including high mechanical strength, high electrical conductivity, high thermal conductivity, being able to carry high current densities, chemically resistant to attacks by strong acids or alkali, and, collectively, extremely high surface area.

CNTs may be grown from a smooth substrate to form a layer of densely packed, vertically aligned CNT pile (morphologically similar to a pile of fiber on a carpet). Such a well-arranged nanostructure has an extremely high surface area. Used in rechargeable batteries or supercapacitors, the CNT layer can store significantly more electrical charge (e.g. lithium ions) than those electrodes made with conventional materials such as graphite. The use of the CNT technology not only enables the energy storage unit to provide long and stable power as in a conventional battery, but also enables the quick burst of high energy that is typical of a supercapacitor.

In this disclosure, a process for producing highly packed and vertically aligned CNT structure on a flexible substrate is described. The flexible CNT structure thus resulted can be directly used in making electrodes for batteries and supercapacitors. The process is suitable for mass productions of the nanostructured carbon material and mass production of the energy storage units comprising the nanostructured carbon material.

Also in this disclosure, examples of energy storage systems utilizing the flexible CNT electrodes are described.

### SUMMARY OF THE INVENTION

In a first aspect of the invention, a device is provided. The device comprises a first conductive sheet, a second conductive sheet being substantially parallel to the first conductive sheet, and a layer of a substance placed between the first conductive sheet and the second conductive sheet, the substance allowing migration of free ions therein. At least one of the first conductive sheet and the second conductive sheet comprises a metal foil layer and at least one of the first conductive sheet and the second conductive sheet comprises a carbon nanotube layer, the carbon nanotube layer being adjacent to the layer of the substance. The carbon nanotube layer is grown on the metal foil layer.

In the device, the first conductive sheet, the layer of the substance and the second conductive sheet form a multi-layered stack, and the device may further comprise a first insulating sheet and a second insulating sheet disposed on outer surfaces of the multi-layered stack, respectively. The device may be dimensioned to have a width and a length that are much larger than a thickness. The device may be rolled up or folded and then hermetically sealed to form an energy storage unit. The energy storage unit may be a rechargeable battery or a capacitor, and the first and the second conductive sheets may be arranged to be connectable with respective terminals of an external electrical energy source or drain.

In the device, the metal foil may comprise one of the following: aluminum, copper, iron, and alloys of aluminum, copper or iron. The metal foil may have a thickness of 5 to 100 microns.

In the device, the carbon nanotube layer may be grown on the metal foil by a process that comprises: coating a catalyst on a surface of the metal foil by low temperature evaporation of the catalyst, annealing the catalyst coated metal foil in ammonia gas at a first temperature; and growing the carbon nanotubes directly on the catalyst coated surface of the metal foil in a hydrocarbon gas atmosphere at a second temperature. The first temperature is lower than the second temperature and the second temperature is no higher than 550° C.

In the device, the layer of the substance may comprise a layer of a porous insulating film and an electrolyte substance disposed on surfaces of the porous insulating film. The porous insulating film may be a membrane made of polyethylene (PE)-polypropylene (PP). The electrolyte substance may be a composite of a lithium salt and one of the following polymers: ethylene carbonate (EC), diethylene carbonate (DC) and propylene carbonate (PC). Or, the electrolyte substance may be a room temperature ionic liquid electrolyte. The room temperature ionic liquid electrolyte may comprise 1-butyl, 3-methylimidazolium chloride ([BMIM][Cl]), 1-25% of cellulose and a lithium salt.

In the device, the carbon nanotubes in the carbon nanotube layer are at least partially aligned in a direction, the direction being at least nearly perpendicular to the surface of the metal foil.

In the second aspect of the invention, a process for forming a layer of carbon nanotubes on a flexible metal foil is provided. The process comprises: coating a catalyst on a surface of the metal foil by low temperature evaporation of the catalyst, annealing the catalyst coated metal foil in ammonia gas at a first temperature, and growing the carbon nanotubes directly on the catalyst coated surface of the metal foil in a hydrocarbon gas atmosphere at a second temperature. The first temperature is lower than the second temperature and the second temperature is no higher than 550° C.

In the process, the metal foil may be one of the following: aluminum, copper, iron, and alloys of aluminum, copper or iron. The metal foil may have a thickness of 5 to 100 microns. The catalyst may comprise one of the following: iron, nickel and cobalt. The catalyst may a particle size of no more than 50 nanometers.

In the process, the carbon nanotubes may be grown to a length of 10 to 100 microns. The carbon nanotubes grown on the metal foil may be at least partially aligned in a direction, the direction being at least nearly perpendicular to the surface of the metal foil. The process is carried out in a chemical vapor deposition system.

In a third aspect of the invention, a device is provided. The device comprises a first energy storage unit; an energy converting unit, configured to convert light energy to electrical energy; a first circuit, configured to transfer at least part of the electrical energy generated by the energy converting unit to the first energy storage unit; a second energy storage unit, configured to provide electrical energy to one or more external circuit; and a second circuit, configured to transfer at least part of the electrical energy stored in the first energy storage unit to the second energy storage unit. At least one of the first and second energy storage units comprises a first conductive sheet, a second conductive sheet being substantially parallel to the first conductive sheet, and a layer of a substance placed between the first conductive sheet and the second conductive sheet, the substance allowing migration of free ions therein. At least one of the first conductive sheet and the second conductive sheet comprises a metal foil layer and a carbon nanotube layer, the carbon nanotube layer being adjacent to the layer of the substance. The carbon nanotube layer is grown on the metal foil layer.

In the device, the energy converting unit comprises one or more photovoltaic cells. The second energy storage unit is placed substantially parallel and adjacent to a surface of the first energy storage unit, and the one or more photovoltaic cells are placed substantially parallel and adjacent to another surface of the first energy storage unit.

In the device, the first circuit is further configured to convert a low voltage electrical charge generated by the energy converting unit into a higher voltage electrical charge suitable for effectively transferring the electrical energy to the first energy storage unit.

Also in the device, the second circuit is further configured to transfer electrical energy from an external energy source to the second energy storage unit if the external energy source is connected to the device, and to transfer at least part of the electrical energy stored in the first energy storage unit to the second energy storage unit if the external energy source is not connected to the device.

### BRIEF DESCRIPTION OF THE DRAWINGS

The features and advantages of the invention will become apparent from a consideration of the subsequent detailed description presented in connection with accompanying drawings, in which:

FIG. 1 is a schematic illustration of a layer of aligned CNTs grown on a flexible metal foil;

FIG. 2 is a Raman scattering spectrum of the CNTs grown on an aluminum foil;

FIG. 3 is a schematic illustration of a multilayered energy storage device structure;

FIG. 4a illustrates the charging mechanism of a lithium ion battery, in which the anode comprises the CNT nanostructure;

FIG. 4b illustrate the discharging mechanisms of the lithium ion battery;

FIG. 5 is a schematic illustration a lithium metal battery in which the cathode comprises CNT nanostructure;

FIG. 6 is a schematic illustration of a supercapacitor in which one or both of the electrodes comprise CNT nanostructure;

FIG. 7 is cyclic voltammetry data of a supercapacitor in which the electrodes are made with CNTs grown on a flexible aluminum foil, compared with a supercapacitor in which the electrodes are made with graphite;

FIG. 8 is an example of a thin film lithium metal/lithium ion battery core that is produced by rolling a multilayered thin film device structure of FIG. 3;

FIG. 9 is a block diagram of an integrated hybrid rechargeable battery-solar cell energy storage system;

FIG. 10 is am exemplary circuit diagram of a boost converter used in the hybrid rechargeable battery-solar cell energy storage unit; and

FIG. 11 is an exemplary construction of the hybrid rechargeable battery-solar cell energy storage unit.

### DETAILED DESCRIPTION

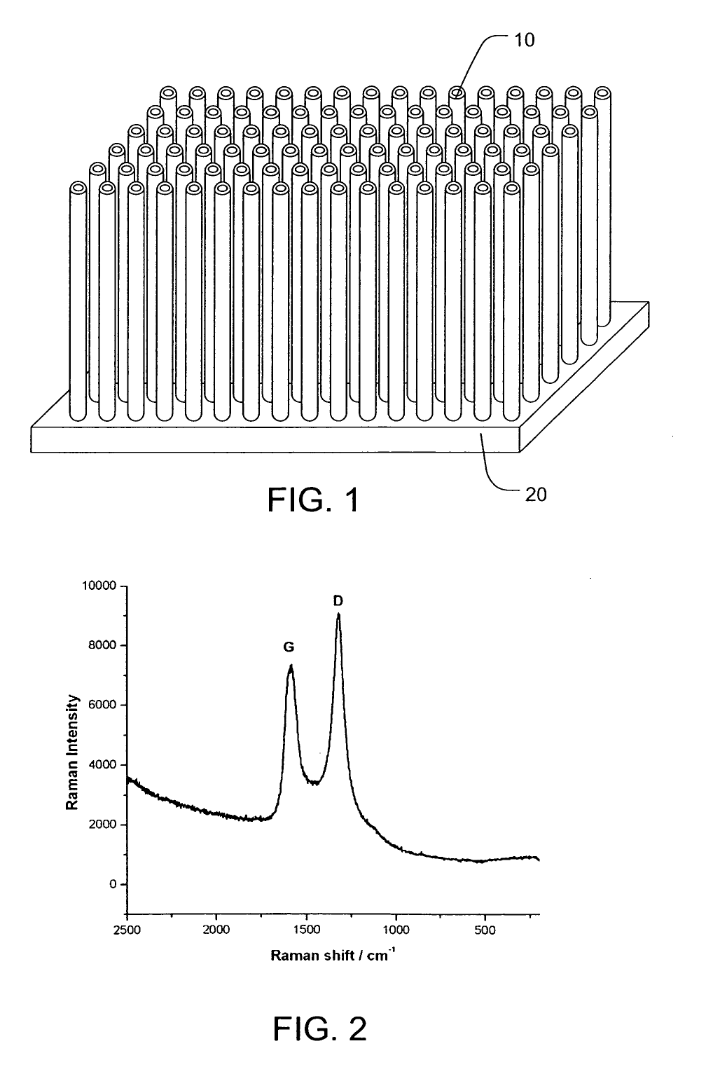

FIG. 1 shows, schematically, a sheet of densely packed, vertically aligned carbon nanotubes 10 grown on a metal foil substrate 20. For achieving a maximum surface area, it is preferred that the CNTs being densely packed (one nanotube next to another with gaps between the nanotubes about the same size as the Li ion) and aligned perpendicular or nearly perpendicular to the surface of the substrate. Also preferably, the carbon nanotubes are multi-walled carbon nanotubes. By directly growing the CNTs on a flexible conductive substrate, the CNTs do not need to be removed from the substrate for been used in the energy storage devices. Since the substrate is flexible, the components of the energy storage devices can be folded or rolled for minimizing the overall volume of the devices. This not only simplifies the manufacturing procedure but also makes it more cost effective.

The growth of the CNTs on the substrate is preferably carried out by a low temperature plasma enhanced chemical vapor deposition (PECVD) method. The deposition process utilizes nanoparticles of a metal catalyst to react with a hydrocarbon gas. In the deposition process, the catalyst decomposes the hydrocarbon gas to produce carbon and hydrogen. The carbon dissolves into the particle and precipitates out from its circumference as the carbon nanotube. Thus, the catalyst acts as a ‘template’ from which the carbon nanotube is formed, and by controlling the catalyst particle size and reaction time, one can tailor the nanotube diameter and length respectively to suit. CNTs, in contrast to solid carbon nanowires, tend to form when the catalyst particle is 50 nm or less.

Typically, the CVD growth temperature is higher than 700° C., which prohibits the use of many thin and flexible substrates. In the present invention, aligned carbon nanotubes are grown directly on thin and flexible metal foils at a temperature no higher than 550° C.

A metal foil is cut to size and cleaned consecutively by acetone and by isopropanol in an ultrasonic bath for 5 minutes each, followed by rinsing with de-ionized water and drying in a nitrogen flow. The metal foil may be made of various metals or alloys such as aluminum (Al), copper (Cu) or stainless steel, preferably Al or Cu. Conventional metal foils can be manufactured by various methods known in the art, so normally these foils are commercially available. The thickness of the metal foil can be from 5 to 100 μm so long as it has sufficient mechanical strength and desired flexibility. Impurities in the metal foil should be sufficiently low so that they do not inhibit the CNT growth and contaminate the growth equipment.

Before the CNT growth, a layer of the catalyst is deposited on the surface of the substrate by low temperature evaporation technique in a DC sputtering system (e.g. at a base pressure of 2.1×10⁻⁶ atm, 20 sccms of argon flow with 50W plasma power for 20 seconds). The thickness of the catalyst layer is less than 5 nanometers. Suitable catalysts include iron (Fe), nickel (Ni) and cobalt (Co). CNT growth is carried out in a quartz vacuum chamber of a chemical vapor deposition (CVD) system. One example of a commercially available CVD system is Aixtron Nanoinstruments Plasma Enhanced Chemical Vapor Deposition system. One or more catalyst-coated substrates are placed on a resistively heated graphite stage in the quartz chamber. Growth temperature is controlled by a thermocouple attached to the surface of the graphite stage. The metal foil substrates are heated up in an ammonia gas (NH₃) atmosphere to 450° C. and annealed at 450° C. for a predetermined period.

After the annealing, the temperature of the graphite stage is ramped up to 520° C. (for Al foil) or to 540° C. (for Cu foil) and acetylene (C₂H₂) was supplied as the carbon feedstock for the CNT growth. After the CNTs have grown to the desired length, the substrates are cooled to room temperature. Nitrogen gas (N₂) was supplied at the end of the growth. It is observed that 15 minutes of growth time may yield 30 to 40 μm long CNTs on an Al foil and 70-80 μm long CNTs on a Cu foil.

The as-grown CNT samples are then inspected by a Raman scattering spectroscopy. FIG. 2 shows a Raman scattering spectrum of the CNTs grown on an Al foil. The multi-walled nanotube structure is confirmed by the D and G bands in the spectrum.

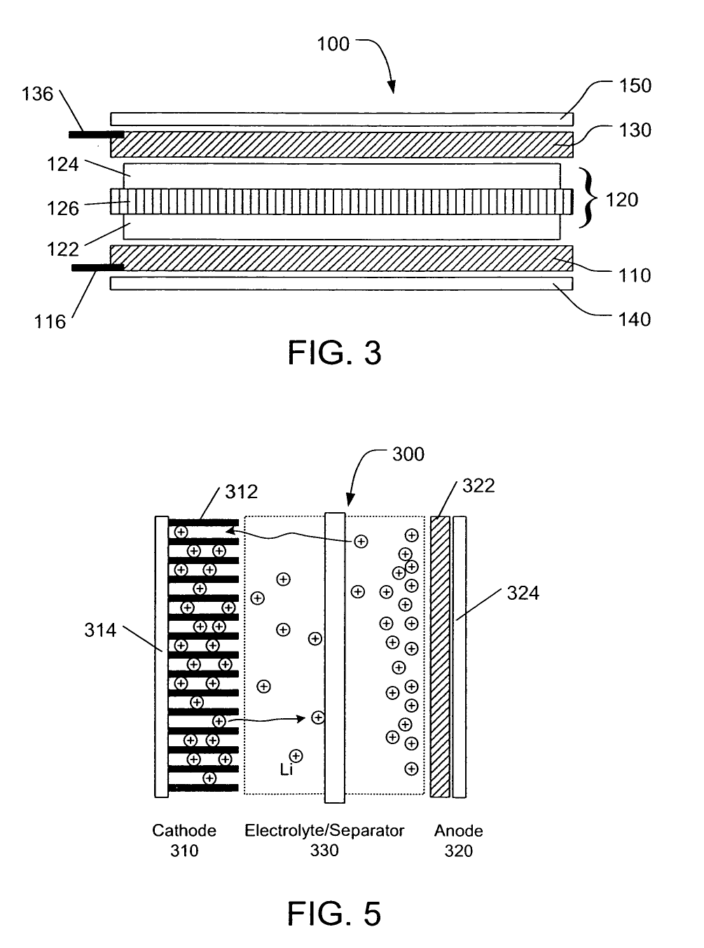

Referring now to FIG. 3, a basic structure of a multi-layered energy storage device 100 comprises a first sheet of a conductive material 110, a layer of a free ion conductive electrolyte/separator 120 disposed on the first sheet of the conductive material 110, and a second sheet of same or different conductive material 130 disposed on the sheet of the electrolyte 120. The first sheet 110, the layer of the electrolyte 120 and the second sheet 130 form a basic multi-layered stack. The first and the second conductive sheets 110 and 130 are used as electrodes (anode and cathode, respectively).

The layer of the electrolyte 120 may have different constructions. One example is that it comprises a separator layer 126. The separator 126 may be a thin sheet of micro-perforated plastic such as a polymer-based membrane, e.g. a 25 μm thick polyethylene (PE)-polypropylene (PP) (trade name CELGARD), or any suitable material such as paper. As the name implies, the separator is an ionic conductor but electric insulator that separates the first and the second conductive sheets while allowing the free ions to pass through. The separator 126 may further filled with or applied thereon an electrolyte (electrolyte layers 122 and 124 on both surfaces of the separator layer 126 are shown). An electrolyte is any substance containing free ions that behaves as an electrically conductive medium. Besides conventional organic electrolytes such as ethylene carbonate (EC), diethylene carbonate (DC) and propylene carbonate (PC), a room temperature ionic liquid (RTIL) electrolyte, for example, 1-butyl, 3-methylimidazolium chloride ([BMIM][Cl]) composing of 1-25% cellulose and a lithium salt, can be preferably used as a gel electrolyte for the fabrication of a fully solid state rechargeable battery. The RTIL gels are non-flammable, flexible and environmentally safe.

The first conductive sheet 110 and/or the second conductive sheet 130 may further comprise a metal foil base layer (acting as a charge collector) and a charge storage or charge supply layer. The charge storages layer may be composed of the carbon nanotube structure and it may be directly grown on the base layer as shown in FIG. 1. The charge supply layer may be composed of a compound, such as a lithium metal oxide, or lithium metal, depending on the type of the device. In the device structure, the charge storage layer and charge supply layer are placed to be adjacent to the electrolyte layer 120. The conductive sheets 110 and 130 may be arranged to be connectable with respective terminals of an external electrical energy source or drain through conductive leads 116 and 136, respectively.

The device structure 100 may further comprise a first insulator sheet 140 and a second insulator sheet 150 disposed on outer surfaces of the multiplayer stack for protection and insulation.

Following is a brief description of various energy storage device structures according to the present invention.

### 1. Lithium Ion Battery Structure

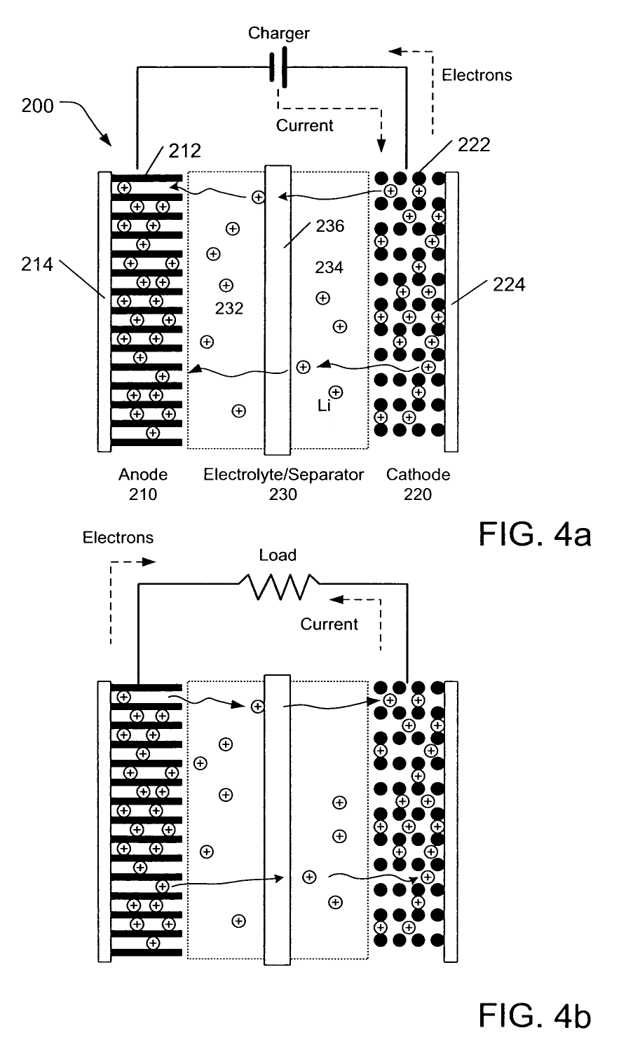

FIGS. 4a and 4b show respectively the charge and discharge mechanisms of a lithium ion battery 200. Inside the battery 200, the anode 210 (negative electrode) is made of a CNT layer 212 directly grown on a metal foil substrate 214, and the cathode 220 (positive electrode) is made of a lithium metal oxide layer 222 and a metal foil charge collector layer 224. Examples of lithium metal oxide include lithium cobalt oxide (LiCoO₂), lithium manganese oxide (LiMnO₄) and lithium nickel oxide (LiNiO₂). A more advanced cathode may be made with LiFePO₄. When the battery is charged, i.e. electrons are supplied to the anode, positively charged lithium ions migrate from the cathode 220 and intercalate into the CNT layer 212 (FIG. 4a). When the battery is discharged, positive lithium ions move back from the anode 210 to replace the missing charges in the cathode 220 (FIG. 4b). In either direction, the lithium ions diffuse through the electrolyte/separator 230, which is composed of a separator layer 236 and electrolyte layers 232 and 234.

### 2. Lithium Metal Battery Structure

FIG. 5 shows a structure of a rechargeable lithium metal battery 300 according to the present invention. Inside the battery 300, the cathode 310 is made of a CNT layer 312 directly grown on a metal foil substrate 314, and the anode 320 is made of a layer of lithium metal 322 and a metal foil charge collector layer 324. When charging or discharging the battery, the lithium ions diffuse through the electrolyte/separator 330.

### 3. Supercapacitor Structure

Like regular capacitors, supercapacitors use the surface of the conductive plates for charge storage. The higher the surface area, generally the higher charge storage capacity. Therefore, high-surface-area CNTs are inherently suitable for use in the supercapacitors. In fact, many of the same materials as used in lithium metal/lithium ion batteries may be used in superpacitors.

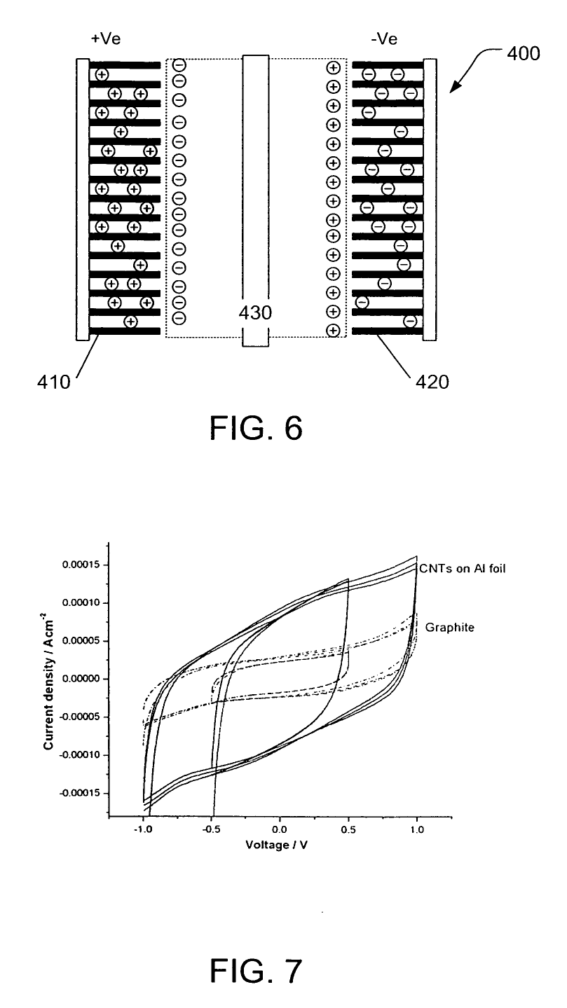

FIG. 6 shows schematically a supercapacitor structure 400 according to the present invention. The structure comprises charge plates 410 and 420, separated by a separator/electrolyte 430. One or both of the charge plates 410 and 420 are composed of CNTs grown on a flexible metal foil for providing extremely high surface areas.

Performance of the CNT electrodes in the supercapacitor can be measured by a so-called cyclic voltammetry (CV) measurement. In the cyclic voltammetry measurement, a voltage source is connected between the CNT electrodes, and the potential between the electrodes is ramped linearly versus time so that the capacitor is charged, until the potential reaches a set point. Then, the potential ramp is inverted, causing the capacitor to discharge. The intensity of the charge and discharge current density is plotted versus the applied voltage to give a cyclic voltammogram trace as current density (mA/cm²) vs. potential (V). The difference of the charging (top) curve, and discharging (bottom) curve on the y-axis, i.e. the width of the voltammogram trace, is proportional to the capacitance of the supercapacitor, which corresponds to the ability of storing the charges. FIG. 7 is exemplary cyclic voltammetry data of a supercapacitor made with CNT-on-aluminum foil electrodes compared with that of a supercapacitor made with graphite electrodes. The data show that the supercapacitor made with the CNT electrodes has much higher capacity and can achieve much higher discharge current density.

Following are some exemplary devices that are based on the above-described multi-layered flexible energy storage device structure.

### 1. A Compact Energy Storage Unit Made by a Rolling Fabrication Process

A particular example is provided to demonstrate how to make compact energy storage units based on the multi-layered device structure of FIG. 3. According to the present invention, at least one of the layers in the multilayered structure is a layer of CNTs grown on a metal foil. In general, each layer in the multilayered structure, including the CNT-on-foil layer, can be prepared by industry scale equipment, and all the layers can be stacked one above another by conventional machinery. Thus, the resulting multilayered stack can be made with much lager width and length than the thickness. The stack can then be rolled or folded to create practical energy storage units.

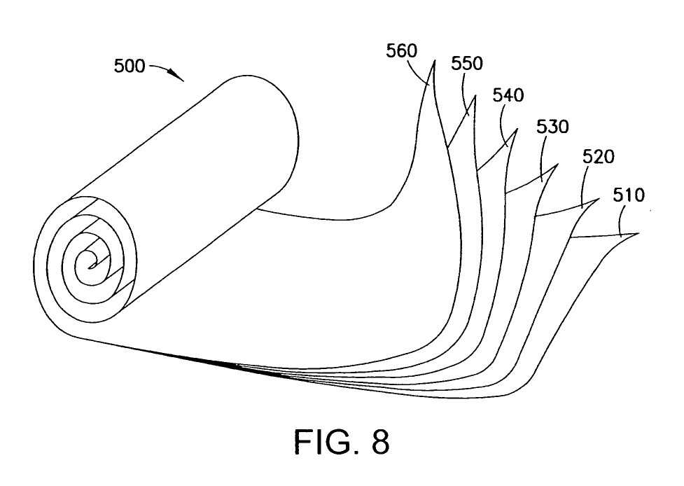

As shown in FIG. 8, a multilayered film roll 500 comprises a first layer of insulator 510, a metal foil charge collector 520, a layer of Li metal foil or lithium metal oxide 530, a layer of separator integrated with solid state lithium electrolyte 540 as mentioned above, a layer of metal foil 550 with CNT structure directly grown thereon, wherein the CNT layer is adjacent to the electrolyte, and a second layer of insulator 560. In this particular example, the multilayer stack 500 is rolled into a cylindrical shape. The roll is then hermetically sealed. Preferably, the fabrication process takes place in an inert gas environment that is oxygen-free (e.g. oxygen level not exceeding 5 ppm).

### 2. A Hybrid Battery-Photovoltaic Cell Power Supply Unit

In this example, a photovoltaic device (such as a solar cell) is integrated with the multilayered energy storage structure, so that the photovoltaic device may convert the light energy into electrical energy and provide the electrical energy to the energy storage device. This solution is especially attractive for powering a portable electronic device when conventional charge supply means such as wall outlets are not available.

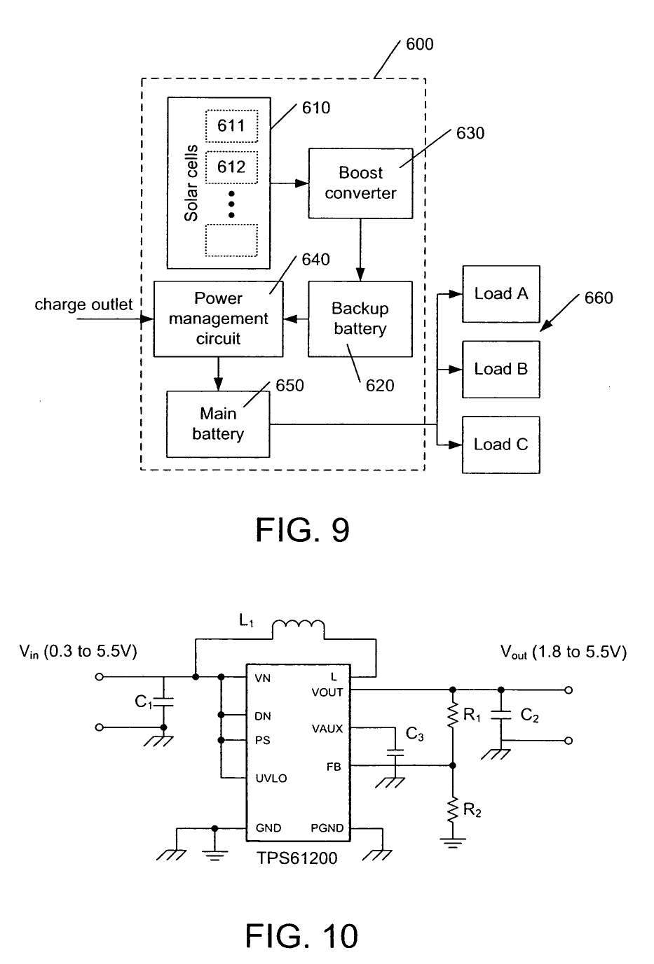

A block diagram of the hybrid battery-photovoltaic cell power supply unit is shown in FIG. 9. The power supply unit 600 comprises a photovoltaic energy converting unit 610, a backup battery 620, a boost converter 630, a power management circuit 640, and a main battery 650. The photovoltaic energy converting unit 610 is configured to convert light energy into electrical energy. It may be, for example, a solar cell array composed of one or solar cells 611, 612, etc. The boost converter 630 is connected between the energy converting unit 610 and the backup battery 620. When in use, it provides at least part of the electrical energy generated by the photovoltaic energy converting unit 610 to the backup battery 620. In order to ensure that the backup battery is always charged with the optimum voltage, independent of the spectrum and intensity of the incident light, the boost converter converts a low voltage electrical charge into a higher voltage electrical charge suitable for effectively charging the backup battery 620. This allows the charging of the battery both in indoors (with fluorescent or incandescent lighting) and outdoors (sunlight). In addition, the boost converter 630 prevents discharging of the backup battery 620 in dark conditions. A sample circuit diagram of the boost converter 630 is shown in FIG. 10, in which the circuit chip TPS61200 is made by Texas Instruments.

Returning to FIG. 9, the electrical charge stored in the backup battery 620 can be supplied to the main battery 650 when the energy storage in the main battery 650 is low. The power management circuit 640 is connected between the backup battery 620 and the main battery 650. It is configured to supply the main battery 650 electrical charges from an external charge source such as a wall outlet, or from the backup battery 620 if the external charge source is not available. The main battery 650 powers various loads 660 of the electronic device.

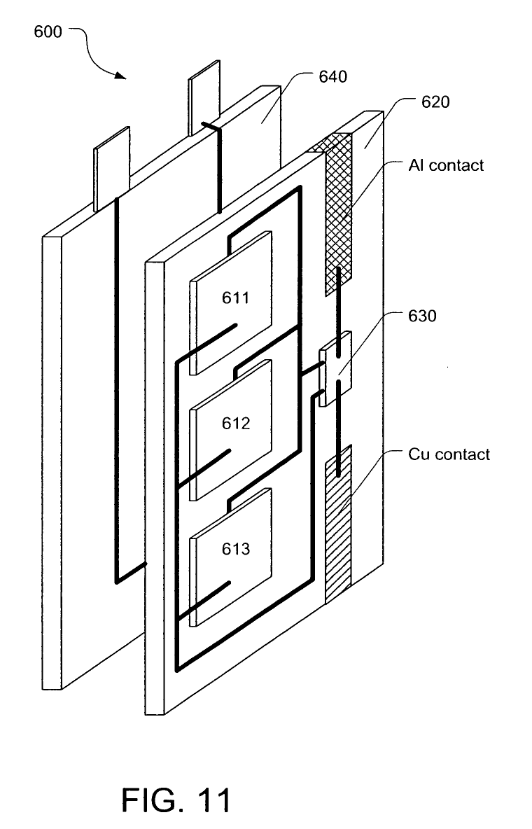

In such a hybrid battery-photovoltaic cell power supply unit, one or both of the backup battery 620 and main battery 650 can be based on the energy storage device structure of the present invention as depicted in FIG. 3, i.e. at least one of the electrodes is made with the CNT structure. One particular arrangement is shown in FIG. 11. A number of photovoltaic devices (611, 612, 613) and a boost converter chip 630 are adhered onto the backup battery 620. Photovoltaic devices are connected in series to provide sufficient voltages. An epoxy sealant may be used for providing the adhesion. Metal contact side of the photovoltaic devices is facing the battery to maximize light absorption. The backup battery 620 is in turn placed next to the main battery 650, may be in a stack-up fashion. Connections between these units can be made via printed conductive paths on the surfaces of these units, no need for hard wiring between the units. The units can be packaged together and sealed as a component. As long as the solar cell array is exposed to a light source (halogen, fluorescent, sun light and so on), it charges the batteries in the power supply unit even if there is no charge source connected to the power supply unit. This power supply unit can be used in various types of portable electronic devices to reduce the need for conventional wall chargers.

Same as the flexible battery structure that can be made in an industrialized fabrication process as described above, the photovoltaic device can also be flexible and be made in industrial scale processes. Examples of the flexible photovoltaic devices include organic photovoltaic cells and dye sensitized solar cells. In addition to these photovoltaic devices, solar cells comprising various types of nanowire network structures may also be considered.

This hybrid battery-photovoltaic cell power supply unit provides autonomous power for portable electronics and may minimize or even eliminate the frequent use of wall chargers. In small devices, this means photovoltaic cell may become the primary source of energy. Integrated hybrid photovoltaic and battery structure enables further packaging advantages for miniaturized or very thin devices. Distributed architecture of the photovoltaic cells enables serialization or parallelization of photovoltaic cell to increase the output voltage, or output current depending on the charged battery to be used, or depending on the charge booster to be used. Use of very thin materials and nanostructures enable further development of transparent photovoltaic cells.

In summary, the present invention provides a process for growing CNT nanostructure on a flexible metal foil substrate and a device structure utilizing the CNT nanostructure. The CNT nanostructure on the metal foil can be directly used in fabricating energy conversion and storage units suitable for portable electronic devices. Due to the extremely large surface area, the aligned CNTs on a metal foils is very advantageous over traditional graphite electrodes.

The device of the present invention can also be extended to incorporate photovoltaic devices and fuel cells. Same electrode structure can also be used in the photovoltaic devices and fuel cells. In addition, other carbon nanostructured materials such as carbon nanohorns and carbon nano-onions may also be deposited directly on such flexible metal substrates. This process can further enable the roll-to-roll fabrication of nanostructured electrodes for industrialized mass production.

It is to be understood that the above-described arrangements are only illustrative of the applications of the principles of the teachings hereof. In particular, it should be understood that although only a few examples have been shown, the teachings hereof are not restricted to those examples. Numerous modifications and alternative arrangements may be devised by those skilled in the art without departing from the scope of the present disclosure.

1. A device, comprising:
a first conductive sheet;
a second conductive sheet being substantially parallel to the first conductive sheet, and
a layer of a substance placed between the first conductive sheet and the second conductive sheet, the substance allowing migration of free ions therein; wherein at least one of the first conductive sheet and the second conductive sheet comprises a metal foil layer and at least one of the first conductive sheet and the second conductive sheet comprises a carbon nanotube layer, the carbon nanotube layer being adjacent to the layer of the substance, and wherein the carbon nanotube layer is grown on the metal foil layer.

2. The device of claim 1, wherein the first conductive sheet, the layer of the substance and the second conductive sheet form a multi-layered stack, and the device further comprises a first insulating sheet and a second insulating sheet disposed on outer surfaces of the multi-layered stack, respectively.

3. The device of claim 2, wherein the device is dimensioned to have a width and a length that are much larger than a thickness, and wherein the device is rolled up or folded and then hermetically sealed to form an energy storage unit.

4. The device of claim 3, wherein the energy storage unit is a rechargeable battery or a capacitor, and the first and the second conductive sheets are arranged to be connectable with respective terminals of an external electrical energy source or drain.

5. The device of claim 1, wherein the metal foil comprises one of the following:
aluminum, copper, iron, and alloys of aluminum, copper or iron.

6. The device of claim 1, wherein the metal foil has a thickness of 5 to 100 microns.

7. The device of claim 1, wherein the carbon nanotube layer is grown on the metal foil by a process that comprises:
coating a catalyst on a surface of the metal foil by low temperature evaporation of the catalyst;
annealing the catalyst coated metal foil in ammonia gas at a first temperature; and
growing the carbon nanotubes directly on the catalyst coated surface of the metal foil in a hydrocarbon gas atmosphere at a second temperature,
wherein the first temperature is lower than the second temperature and the second temperature is no higher than 550° C.

8. The device of claim 1, wherein the layer of the substance comprises a layer of a porous insulating film and an electrolyte substance disposed on surfaces of the porous insulating film.

9. The device of claim 8, wherein the porous insulating film is a membrane made of polyethylene (PE)-polypropylene (PP).

10. The device of claim 8, wherein the electrolyte substance is a composite of a lithium salt and one of the following polymers: ethylene carbonate (EC), diethylene carbonate (DC) and propylene carbonate (PC).

11. The device of claim 8, wherein the electrolyte substance is a room temperature ionic liquid electrolyte.

12. The device of claim 11, wherein the room temperature ionic liquid electrolyte comprises 1-butyl, 3-methylimidazolium chloride ([BMIM][Cl]), 1-25% of cellulose and a lithium salt.

13. The device of claim 1, wherein the carbon nanotubes in the carbon nanotube layer are at least partially aligned in a direction, said direction being at least nearly perpendicular to the surface of the metal foil.

14. A process for forming a layer of carbon nanotubes on a flexible metal foil, comprising:
coating a catalyst on a surface of the metal foil by low temperature evaporation of the catalyst;
annealing the catalyst coated metal foil in ammonia gas at a first temperature; and
growing the carbon nanotubes directly on the catalyst coated surface of the metal foil in a hydrocarbon gas atmosphere at a second temperature,
wherein the first temperature is lower than the second temperature and the second temperature is no higher than 550° C.

15. The process of claim 14, wherein the metal foil is one of the following: aluminum, copper, iron, and alloys of aluminum, copper or iron.

16. The process of claim 15, wherein the metal foil has a thickness of 5 to 100 microns.

17. The process of claim 14, wherein the catalyst comprises one of the following: iron, nickel and cobalt.

18. The process of claim 14, wherein the catalyst has a particle size of no more than 50 nanometers.

19. The process of claim 14, wherein the carbon nanotubes are grown to a length of 10 to 100 microns.

20. The process of claim 14, wherein the carbon nanotubes grown on the metal foil are at least partially aligned in a direction, said direction being at least nearly perpendicular to the surface of the metal foil.

21. The process of claim 14, wherein the process is carried out in a chemical vapor deposition system.

22. A device, comprising:
a first energy storage unit,
an energy converting unit, configured to convert light energy to electrical energy,
a first circuit, configured to transfer at least part of the electrical energy generated by the energy converting unit to the first energy storage unit,
a second energy storage unit, configured to provide electrical energy to one or more external circuit, and
a second circuit, configured to transfer at least part of the electrical energy stored in the first energy storage unit to the second energy storage unit,
wherein at least one of the first and second energy storage units comprises:
a first conductive sheet,
a second conductive sheet being substantially parallel to the first conductive sheet, and
a layer of a substance placed between the first conductive sheet and the second conductive sheet, the substance allowing migration of free ions therein;
wherein at least one of the first conductive sheet and the second conductive sheet comprises a metal foil layer and at least one of the first conductive sheet and the second conductive sheet comprises a carbon nanotube layer, the carbon nanotube layer being adjacent to the layer of the substance,
and wherein the carbon nanotube layer is grown on the metal foil layer.

23. The device of claim 22, wherein the energy converting unit comprises one or more photovoltaic cells.

24. The device of claim 23, wherein the second energy storage unit is placed substantially parallel and adjacent to a surface of the first energy storage unit, and the one or more photovoltaic cells are placed substantially parallel and adjacent to another surface of the first energy storage unit.

25. The device of claim 23, wherein the first circuit is further configured to convert a low voltage electrical charge generated by the energy converting unit into a higher voltage electrical charge suitable for effectively transferring the electrical energy to the first energy storage unit.

26. The device of claim 23, wherein the second circuit is further configured to transfer electrical energy from an external energy source to the second energy storage unit if the external energy source is connected to the device, and to transfer at least part of the electrical energy stored in the first energy storage unit to the second energy storage unit if the external energy source is not connected to the device.
